(19) United States
(12) Patent Application Publication
(10) Pub. No.: US 2025/0306537 A1
(43) Pub. Date: Oct. 2, 2025

(54) ATOMIC OSCILLATOR

(71) Applicant: NEC Corporation, Tokyo (JP)

(72) Inventor: Sota KAGAMI, Tokyo (JP)

(73) Assignee: NEC Corporation, Tokyo (JP)

(21) Appl. No.: 19/070,594

(22) Filed: Mar. 5, 2025

(30) Foreign Application Priority Data
Mar. 28, 2024 (JP) 2024-054331

(51) Int. Cl. G04F 5/14; H03L 7/26

(52) U.S. Cl. CPC G04F 5/145; H03L 7/26

(57) ABSTRACT

An atomic oscillator of the present disclosure includes a first laser device that applies a first laser light from a plurality of directions to a glass cell in which alkali metal atoms are enclosed, and a second laser device that applies a second laser light to the glass cell. The atomic oscillator is configured in such a manner that the first laser light from one of the directions and the second laser light are made to enter the glass cell through the same optical path.

### INCORPORATION BY REFERENCE

This application is based upon and claims the benefit of priority from Japanese patent application No. 2024-054331, filed on Mar. 28, 2024, the disclosure of which is incorporated herein in its entirety by reference.

### TECHNICAL FIELD

The present invention relates to an atomic oscillator.

### BACKGROUND ART

An atomic oscillator is a device that measures the exact time based on the natural frequency of an atom. In a small atomic clock, the natural frequency of an atom is measured using CPT (Coherent Population Trapping), which is a quantum interference effect that occurs when excitation light of two frequencies is applied to an alkali metal atomic gas, as the oscillation principle of an atomic oscillator. In CPT, when the difference between the two excitation light frequencies matches the transition frequency between the alkali metal ground levels, the amount of transmitted light increases without the absorption of the excitation light occurring. Therefore, in an atomic oscillator with CPT as the operation principle, the difference between the two excitation light frequencies is swept, and the resonance frequency that is the difference between the frequencies at which the amount of transmitted light reaches the maximum is used as the natural frequency of the atom. One of the performance indexes of an atomic oscillator is whether the natural frequency of the atom can be acquired stably over a long period of time.

Here, in the CPT-type atomic oscillator, the line width of the CPT resonance contributes to the frequency accuracy. Therefore, as described in Patent Literature 1, an atomic oscillator of magneto-optical trap type that narrows the line width is known. To be specific, in the atomic oscillator of magneto-optical trap type, a quadrupole magnetic field is generated in a glass cell containing alkali metal gas, and laser light of specific circular polarization is applied to the center thereof from six directions to spatially trap an atomic population.
Patent Literature 1: Japanese Unexamined Patent Application Publication No. JP-A 2020-141401

However, as described above, it is necessary to apply laser light from a plurality of optical axis directions in an atomic oscillator of magneto-optical trap type. Therefore, the number of jigs and optical elements to be used increases, the shape of a glass cell becomes complicated, and moreover anti-reflection film coating is required on both sides of the glass, causing a problem of difficulty in cost reduction and size reduction.

### SUMMARY OF THE INVENTION

Accordingly, an object of the present disclosure is to solve the abovementioned problem of difficulty in cost reduction and cost reduction in an atomic oscillator of magneto-optical trap type.

An atomic oscillator as an aspect of the present disclosure includes a first laser device that applies a first laser light from a plurality of directions to a glass cell in which alkali metal atoms are enclosed and a second laser device that applies a second laser light to the glass cell, and is configured in such a manner that the first laser light from one of the directions and the second laser light are made to enter the glass cell through a same optical path.

With the configurations as described above, the present disclosure can achieve the cost reduction and size reduction in an atomic oscillator of magneto-optical trap type.

### BRIEF DESCRIPTION OF THE DRAWINGS

FIG. 1 is a diagram illustrating a configuration of an atomic oscillator in the present disclosure;

FIG. 2 is a diagram illustrating a configuration of an atomic oscillator in the present disclosure; and

FIG. 3 is a diagram illustrating a configuration of an atomic oscillator in the present disclosure.

### EXAMPLE EMBODIMENTS

### First Example Embodiment

A first example embodiment of the present disclosure will be described with reference to the drawings. The drawings may be associated with any of the example embodiments.

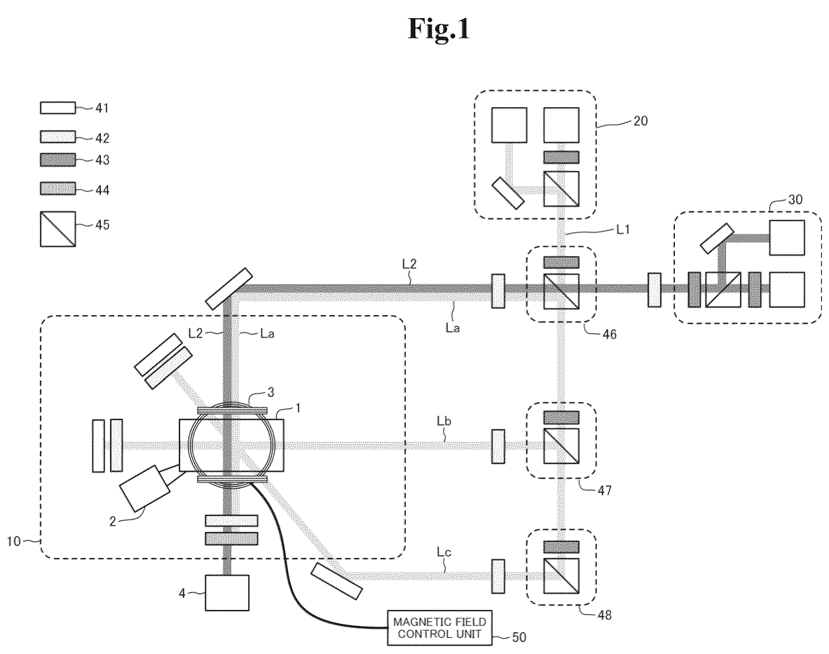

FIG. 1 shows the overview of a configuration of an atomic oscillator in this example embodiment. The atomic oscillator in this example embodiment is a CPT-type atomic oscillator including a magneto-optical trap unit 10, and includes a glass cell 1 with alkali atom gas being enclosed inside, an ion pump 2, a magnetic field coil 3, and an optical detector 4 that detects transmitted light having passed through the glass cell 1. Then, the atomic oscillator includes a trapping laser unit 20 for performing magneto-optical trap, a measuring laser unit 30 for measuring the CPT resonance frequency, and optical elements to which laser lights are applied by the abovementioned units, such as a mirror 41, a λ/4 wave plate 42, a λ/2 wave plate 43, a bandpass characteristic optical element 44, and a polarized beam splitter 45. Furthermore, the atomic oscillator includes a magnetic field control unit 50 that controls the magnetic field by the magnetic field coil 3, and a control unit (not shown) that controls the operation of the atomic oscillator itself. The respective components will be described in detail below.

In this example embodiment, the glass cell 1 a cell formed in a substantially cuboid in which a predetermined surface is formed in a plane, and an alkali metal gas is enclosed inside. The alkali metal gas is, for example, cesium. Then, inside the glass cell 1, the magnetic field is controlled by the magnetic field coil 3 and the magnetic field control unit 50, and a quadrupole magnetic field is generated, for example. Then, as will be described later, a trapping laser light L1 is applied to the glass cell 1 to trap the alkali metal gas in the glass cell 1, and the magneto-optical trap unit 10 is formed by an optical element and so forth including the glass cell 1. The shape of the glass cell 1 is not limited to the shape described above.

The trapping laser unit 20 (first laser device) emits the trapping laser light L1 (first laser light) that is applied from a plurality of directions in order to trap the alkali metal gas in the glass cell 1. To be specific, the trapping laser unit 20 emits the trapping laser light L1 including at least two wavelengths such as trap light and repump light having a wavelength of around 852 nm corresponding to the D2 line of cesium.

Then, the trapping laser light L1 emitted by the trapping laser unit 20 is branched into a plurality of trap laser lights La, Lb, and Lc at light branching units 46, 47, and 48 (branching units) as shown in FIG. 1. Here, the light branching units 46, 47, and 48 each include a λ/2 wave plate 43 and a polarized beam splitter 45, and control power transmitted by the beam splitter and power reflected by the beam splitter in accordance with the angle of the λ/2 wave plate. In this example embodiment, the three light branching units 46, 47, and 48 are provided. The power of one-third of the trapping laser light L1 is reflected by the first light branching unit 46 and made to enter the magneto-optical trap unit 10 as the first laser light La, the power of one-half of the transmitted light by the first light branching unit 46 is reflected by the second light branching unit 47 and made to enter the magneto-optical trap unit 10 as the second laser light Lb, and the power of the maximum power of the transmitted light by the second light branching unit 47 is reflected by the third light branching unit 48 and made to enter the magneto-optical trap unit 10 as the third laser light Lc. The light branching units 46, 47, and 48 described above may be each configured with an optical fiber coupler and a lens.

Then, as shown in FIG. 1, the abovementioned three trapping laser lights La, Lb, and Lc are transmitted through the 4/λ wave plate 42 and reflected by the mirrors 41, and they are made to orthogonally enter the magneto-optical trap unit 10. At this time, after made to enter the glass cell 1 and transmitted through the glass cell 1, respectively, the second trapping laser light Lb and the third trapping laser light Lc are reflected by the mirrors 41 and again made to enter the glass cell 1 from the opposite side. Moreover, after made to enter the glass cell 1 and transmitted through the glass cell 1, the first trapping laser light La is reflected by the bandpass characteristic optical element 44 and again made to enter the glass cell 1 from the opposite side. The bandpass characteristic optical element 44 is an optical element having a bandpass wavelength characteristic that reflects the trapping laser light L1 (La) and transmits a measuring laser light L2 to be described later. That is to say, the bandpass characteristic optical element 44 is a reflective-type bandpass filter that transmits only a laser light having a wavelength of around 895 nm that is the measuring laser light L2 to be described later.

Thus, the first trapping laser light La, the second trapping laser light Lb, and the third trapping laser light Lc are once made to enter the glass cell 1, transmitted and then reflected, and are again made to enter the glass cell 1 from the opposite side that is the transmission side. That is to say, the trapping laser lights La, Lb, and Lc enter the glass cell 1 from two directions, respectively, and in total, they enter from six directions. Thus, it is possible to perform spatial trapping of an atomic population by applying the trapping laser lights La, Lb, and Lc to the alkali metal gas in the glass cell 1 from a plurality of directions.

The measuring laser unit 30 (second laser device) emits a measuring laser light for measurement of the resonance frequency. To be specific, the trapping laser unit 20 emits the measuring laser light L2 including two laser lights having a wavelength of around 895 nm corresponding to the D1 line of cesium.

Then, the measuring laser light L2 emitted by the measuring laser unit 30 is made to enter the first light branching unit 46 (wave synthesizing unit) and synthesized with the first trapping laser light La branched by the first light branching unit 46, as shown in FIG. 1. To be specific, the first light branching unit 46 makes the measuring laser light L2 enter and transmits toward the branch direction of the first trapping laser light La that is the trapping laser light L1 made to enter and branched, and thereby synthesizes the first trapping laser light La with the measuring laser light L2. As a result, the first trapping laser light La and the measuring laser light L2 are synthesized in the same optical path.

Then, the first trapping laser light La and the measuring laser light L2 synthesized in the same optical path are reflected by the mirror 41 and enter the glass cell 1 following the same optical path, as shown in FIG. 1. At this time, the first trapping laser light La and the measuring laser light L2 are set to enter perpendicularly to the plane of the glass cell 1.

The first trapping laser light La and the measuring laser light L2 made to enter the glass cell 1 in the same optical path are transmitted through the glass cell 1 following the same optical path, and furthermore enter the bandpass characteristic optical element 44 placed on the optical path of the transmitted light. Then, the first trapping laser light La is reflected by the bandpass characteristic optical element 44 as mentioned above, while the measuring laser light L2 is transmitted through the bandpass characteristic optical element 44. This is because, as mentioned above, the bandpass characteristic optical element 44 is a reflective-type bandpass filter that transmits only a laser light having a wavelength of around 895 nm, which is the measuring laser light L2.

Since the measuring laser light L2 is thus transmitted through the bandpass characteristic optical element 44 after transmitted through the glass cell 1, the measuring laser light L2 can be detected by the optical detector 4 placed in the optical path of the transmitted light. Therefore, by detecting the transmitted light of the measuring laser light L2 transmitted through the glass cell 1 by using the optical detector 4, it is possible to identify the resonance frequency necessary for the operation of the atomic oscillator and achieve the activation of the atomic oscillator. At the time of actual activation, immediately after the trapping laser light L1 (La, Lb, and Lc) is first applied to generate a magneto-optical trap, the intensity of the trapping laser light L1 is weakened, and the measuring laser L2 is applied to measure the resonance frequency.

As described above, according to the present disclosure, the optical path of one trapping laser light La for performing magneto-optical trap and the optical path of the measuring laser light L2 are made to be in the same optical path, and these laser lights are made to enter the glass cell 1. Consequently, it is possible to suppress the provision of optical paths more than optical paths necessary for performing magneto-optical trap, thereby suppressing the increase in the number of jigs and optical elements to be used, and furthermore suppressing the complication of the shape of the glass cell. As a result, it is possible to achieve the cost reduction and size reduction of an atomic oscillator of magneto-optical trap type.

### Second Example Embodiment

Next, a second example embodiment of the present disclosure will be described with reference to the drawings. The drawings may be associated with any of the example embodiments.

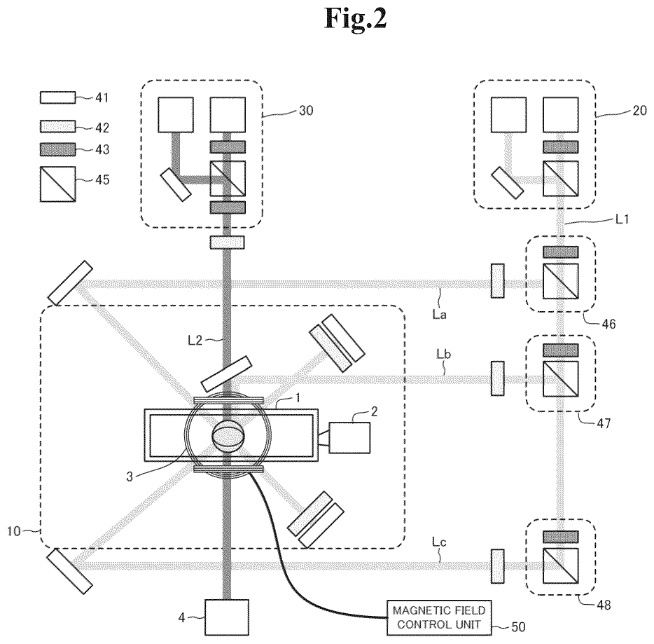

FIG. 2 shows the overview of a configuration of an atomic oscillator in this example embodiment. The atomic oscillator in this example embodiment includes the trapping laser unit 20, the measuring laser unit 30, the mirror 41, the λ/4 wave plate 42, the λ/2 wave plate 43, and the polarized beam splitter 45, as in the first example embodiment. In this example embodiment, unlike in the first example embodiment, the bandpass characteristic optical element described above is not provided, and the optical paths of the laser lights La, Lb, Lc, and L2 are formed in a different manner due to the difference in arrangement of the mirror 41 and so forth. Hereinafter, a configuration different from that of the other example embodiment described above will be mainly described in detail.

The trapping laser light L1 in this example embodiment is branched into the trapping laser lights La, Lb, and Lc by the light branching units 46, 47, and 48 as shown in FIG. 2. Then, the trapping laser lights La, Lb, and Lc are reflected by the mirrors 41 as in the first example embodiment, and thereby enters the glass cell 1 by moving back and forth. At this time, the second trapping laser light Lb is reflected by the mirror 41 in the perpendicular direction to the paper surface of FIG. 2 and is made to enter the glass cell 1, and after transmitted through the glass cell 1, the second trapping laser light Lb is transmitted through the λ/4 wave plate 42 (not shown) located on the opposite side of the glass cell 1 and is reflected by the mirror 41 (not shown), and again the second trapping laser light Lb is transmitted through the λ/4 wave plate 42 and is made to enter the glass cell 1. That is to say, when the transverse direction is the X direction, the longitudinal direction is the Y direction, and the vertical direction to the paper surface is the Z direction in FIG. 2, the mirrors 41 are arranged on the front side and the back side of the paper surface across the glass cell 1, and the second trapping laser light Lb enters the glass cell 1 by moving back and forth along the Z direction.

Further, the measuring laser light L2 enters the glass cell 1 along the Y direction in FIG. 2. Consequently, in the same manner as described above, it is possible to, immediately after applying the trapping laser light L1 (La, Lb, and Lc) to generate a magneto-optical trap, weaken the intensity of the trapping laser light L1 and apply the measuring laser L2 to measure the resonance frequency.

### Third Example Embodiment

Next, a third example embodiment of the present disclosure will be described with reference to the drawings. The drawings may be associated with any of the example embodiments.

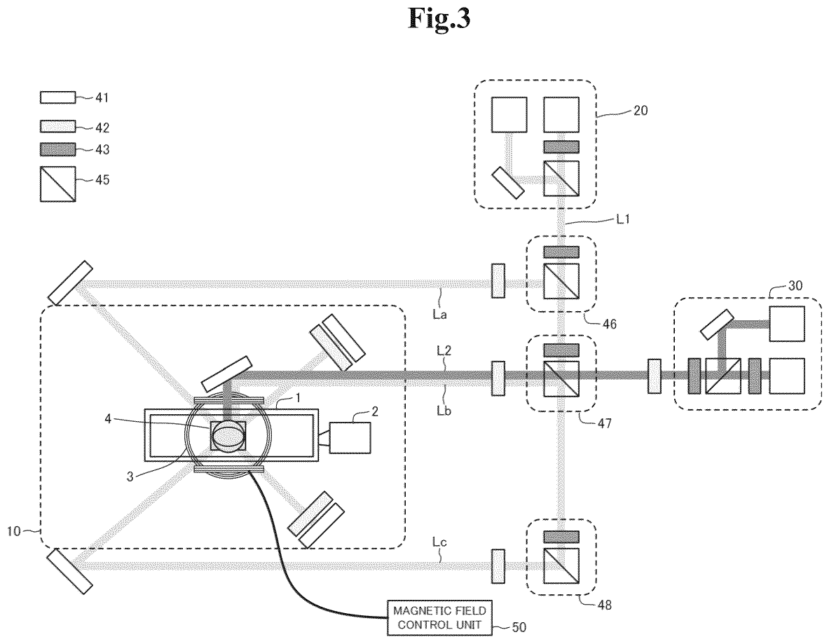

FIG. 3 shows the overview of a configuration of an atomic oscillator in this example embodiment. The atomic oscillator in this example embodiment includes the trapping laser unit 20, the measuring laser unit 30, the mirror 41, the λ/4 wave plate 42, the λ/2 wave plate 43, the bandpass characteristic optical element, and the polarized beam splitter 45, as in the first example embodiment. In this example embodiment, the arrangement of the mirrors 41 and so forth is different from that in the above-described first and second example embodiments. Hereinafter, a configuration different from those of the above-described example embodiments will be mainly described in detail.

The trapping laser light L1 in this example embodiment is branched into the trapping laser lights La, Lb, and Lc by the light branching units 46, 47, and 48 as shown in FIG. 3. Then, the trapping laser lights La, Lb, and Lc are reflected by the mirrors 41 as in the second example embodiment, and thereby enter the glass cell 1 by moving back and forth. At this time, in this configuration, the measuring laser light L2 enters the glass cell 1 following the same optical path as the second trapping laser light Lb.

Furthermore, in this example embodiment, the optical detector 4 is installed inside the glass cell 1. At this time, by providing a bandpass characteristic optical element (not shown) having a wavelength characteristic that transmits only the measuring laser light L2 on the surface of the optical detector 4, it is possible to measure only the measuring laser light L2 by using the optical detector 4, and it is possible to reflect the second trapping laser light Lb in the same optical path.

Consequently, in the same manner as described above, it is possible to, immediately after applying the trapping laser light L1 (La, Lb, and Lc) to generate a magneto-optical trap, weaken the intensity of the trapping laser light L1 and apply the measuring laser L2 to measure the resonance frequency.

Although the present invention has been described above with reference to the above example embodiments, the present invention is not limited to the above example embodiments. The configuration and details of the present invention can be changed in various manners that can be understood by those skilled in the art within the scope of the present invention.

### Supplementary Notes

The whole or part of the example embodiments disclosed above can be described as the following supplementary notes. Below, the overview of the configuration of the atomic oscillator in the present invention will be described. However, the present invention is not limited to the following configurations.

### (Supplementary Note 1)

An atomic oscillator comprising a first laser device configured to apply a first laser light from a plurality of directions to a glass cell in which alkali metal atoms are enclosed and a second laser device configured to apply a second laser light to the glass cell, wherein
the first laser light from one of the directions and the second laser light are made to enter the glass cell through a same optical path.

### (Supplementary Note 2)

The atomic oscillator according to supplementary note 1, further comprising
an optical detector configured to detect transmission light transmitted through the glass cell, wherein
an optical element configured to not transmit the first laser light but transmit the second laser light toward the optical detector is placed on an optical path of the transmission light.

### (Supplementary Note 3)

The atomic oscillator according to supplementary note 2, wherein
the optical element placed on the optical path of the transmission light is configured to reflect the first laser light toward the glass cell and transmit the second laser light toward the optical detector.

### (Supplementary Note 4)

The atomic oscillator according to supplementary note 1, further comprising
a wave synthesizing unit configured to make part of the first laser light and the second laser light enter from mutually different optical paths, reflect the part of first laser light and transmit the second laser light, thereby synthesizing as the first laser light from the one direction and the second laser light in the same optical path.

### (Supplementary Note 5)

The atomic oscillator according to supplementary note 1, further comprising:
a branching unit configured to branch the first laser light emitted by the first laser device into a plurality of the first laser lights made to enter the glass cell from the plurality of directions; and
a synthesizing unit configured to make one of the first laser lights obtained by branching and the second laser light enter from mutually different optical paths, reflect the one first laser lights and transmit the second laser light, thereby synthesizing as the first laser light from the one direction and the second laser light in the same optical path.

### (Supplementary Note 6)

The atomic oscillator according to supplementary note 1, further comprising
a synthesizing unit configured to branch the first laser light emitted by the first laser device into a plurality of the first laser lights made to enter the glass cell from the plurality of directions, and configured to make the second laser light enter and transmit toward a direction of one of the first laser lights obtained by branching, thereby synthesizing as the first laser light from the one direction and the second laser light in the same optical path.

### (Supplementary Note 7)

The atomic oscillator according to supplementary note 1, wherein
the first laser light from the one direction and the second laser light perpendicularly are made to enter a plane of the glass cell through the same optical path.

### (Supplementary Note 8)

The atomic oscillator according to supplementary note 1, wherein:
the first laser device applies the first laser light for trapping the alkali metal atoms from the plurality of directions; and
the second laser device applies the second laser light for measuring a resonance frequency.

### DESCRIPTION OF REFERENCE NUMERALS

1 glass cell
2 ion pump
3 magnetic field coil
4 optical detector
10 magneto-optical trap unit
20 trapping laser unit
30 measuring laser unit
41 mirror
42 λ/4 wave plate
43 λ/2 wave plate
44 polarized beam splitter
45 bandpass characteristic optical element
46 first light branching unit
47 second light branching unit
48 third light branching unit
50 magnetic field control unit

1. An atomic oscillator comprising a first laser device configured to apply a first laser light from a plurality of directions to a glass cell in which alkali metal atoms are enclosed and a second laser device configured to apply a second laser light to the glass cell, wherein
the first laser light from one of the directions and the second laser light are made to enter the glass cell through a same optical path.

2. The atomic oscillator according to claim 1, further comprising
an optical detector configured to detect transmission light transmitted through the glass cell, wherein
an optical element configured to not transmit the first laser light but transmit the second laser light toward the optical detector is placed on an optical path of the transmission light.

3. The atomic oscillator according to claim 2, wherein
the optical element placed on the optical path of the transmission light is configured to reflect the first laser light toward the glass cell and transmit the second laser light toward the optical detector.

4. The atomic oscillator according to claim 1, further comprising
a wave synthesizing unit configured to make part of the first laser light and the second laser light enter from mutually different optical paths, reflect the part of first laser light and transmit the second laser light, thereby synthesizing as the first laser light from the one direction and the second laser light in the same optical path.

5. The atomic oscillator according to claim 1, further comprising:
a branching unit configured to branch the first laser light emitted by the first laser device into a plurality of the first laser lights made to enter the glass cell from the plurality of directions; and
a synthesizing unit configured to make one of the first laser lights obtained by branching and the second laser light enter from mutually different optical paths, reflect the one first laser lights and transmit the second laser light, thereby synthesizing as the first laser light from the one direction and the second laser light in the same optical path.

6. The atomic oscillator according to claim 1, further comprising
a synthesizing unit configured to branch the first laser light emitted by the first laser device into a plurality of the first laser lights made to enter the glass cell from the plurality of directions, and configured to make the second laser light enter and transmit toward a direction of one of the first laser lights obtained by branching, thereby synthesizing as the first laser light from the one direction and the second laser light in the same optical path.

7. The atomic oscillator according to claim 1, wherein
the first laser light from the one direction and the second laser light perpendicularly are made to enter a plane of the glass cell through the same optical path.

8. The atomic oscillator according to claim 1, wherein:
the first laser device applies the first laser light for trapping the alkali metal atoms from the plurality of directions; and
the second laser device applies the second laser light for measuring a resonance frequency.
